(19) United States
(12) Patent Application Publication
(10) Pub. No.: US 2026/0305026 A1
(43) Pub. Date: Oct. 1, 2026

(54) OPTOELECTRONIC COMPONENT AND METHOD OF PRODUCING AN OPTOELECTRONIC COMPONENT

(71) Applicant: ams-OSRAM International GmbH, Regensburg (DE)

(72) Inventor: Theo Kaiser, Köfering (DE)

(21) Appl. No.: 18/996,450

(22) PCT Filed: Jul. 25, 2023
(86) PCT No.: PCT/EP2023/070567

§ 371 Date: Jan. 17, 2025

(30) Foreign Application Priority Data
Aug. 5, 2022 (DE) 10 2022 119 750.6

(51) Int. Cl. H10H 20/857; H10H 20/01; H10H 20/85

(52) U.S. Cl. CPC H10H 20/857; H10H 20/0364; H10H 20/8504

(57) ABSTRACT

In an embodiment an optoelectronic component includes a carrier with a main surface, the carrier including a ceramic, an optoelectronic semiconductor chip arranged on the main surface of the carrier and a frame laterally at least partially enclosing the carrier, wherein at least the main surface of the carrier has a metallic coating, wherein an area of the carrier directly in contact with the frame is partially free of the metallic coating, and wherein the metallic coating has a thickness between 10 nanometers and 10 micrometers, inclusive.

### CROSS-REFERENCE TO RELATED APPLICATIONS

This patent application is a national phase filing under section 371 of PCT/EP2023/070567, filed Jul. 25, 2023, which claims the priority of German patent application no. 102022119750.6, filed Aug. 5, 2022, each of which is incorporated herein by reference in its entirety.

### TECHNICAL FIELD

An optoelectronic component and a method for producing an optoelectronic component are disclosed.

### SUMMARY

Embodiments provide an optoelectronic component with improved mechanical, chemical, optical and/or electro-optical properties, as well as a method for producing such an optoelectronic component.

According to at least one embodiment, the optoelectronic component comprises a carrier with a main surface. In particular, the carrier mechanically stabilizes the optoelectronic component. Furthermore, the carrier is configured for dissipating heat generated during operation of the optoelectronic component, for example. In particular, the carrier comprises a ceramic or a metal, for example copper or aluminum, or consists of one of these materials.

The carrier preferably comprises electrical contact surfaces for external electrical contacting of the optoelectronic component. The electrical contact surfaces are arranged, for example, on a back side surface of the carrier. Here and in the following, the back side surface refers to a surface of the carrier opposite to the main surface. The electrical contact surfaces can also be configured for an external mechanical attachment of the optoelectronic component. In particular, the optoelectronic component can be surface-mountable.

According to at least one further embodiment, the optoelectronic component comprises an optoelectronic semiconductor chip arranged on the main surface of the carrier. For example, the optoelectronic semiconductor chip is bonded or soldered to the main surface of the carrier. In particular, the optoelectronic semiconductor chip generates electromagnetic radiation during operation and/or the optoelectronic semiconductor chip is configured for detecting electromagnetic radiation. In other words, the optoelectronic semiconductor chip is an emitter and/or a detector, for example.

In particular, the optoelectronic semiconductor chip converts an electric current into the electromagnetic radiation and/or converts electromagnetic radiation incident on the optoelectronic semiconductor chip into an electric current. For example, the optoelectronic semiconductor chip emits and/or detects electromagnetic radiation in a spectral range between infrared and ultraviolet light. Preferably, the optoelectronic semiconductor chip emits and/or detects electromagnetic radiation in a visible spectral range.

The optoelectronic semiconductor chip is, for example, a light-emitting diode, a photodiode or a phototransistor. In particular, the optoelectronic semiconductor chip comprises an epitaxial semiconductor layer stack with an active layer. The active layer comprises, for example, a pn-junction configured for converting the electric current into electromagnetic radiation, or vice versa.

According to at least one further embodiment, the optoelectronic component comprises a frame which laterally at least partially encloses the carrier. Preferably, the frame completely encloses the carrier laterally. Here and in the following, “lateral” refers to directions parallel to the main surface of the carrier. In particular, the frame is in direct contact with the carrier at least in places.

For example, the frame is configured for protecting the optoelectronic semiconductor chip from external environmental influences. For example, the frame protects the optoelectronic semiconductor chip from mechanical forces, moisture and/or harmful substances, such as H₂S, SO₂, Cl₂, NOₓ.

Furthermore, the frame can be configured for deflecting electromagnetic radiation. For this purpose, the frame in particular comprises an at least partially reflective material and/or an at least partially reflective layer for the electromagnetic radiation is applied to the surface of the frame. For example, the frame deflects electromagnetic radiation that is emitted by the optoelectronic semiconductor chip in lateral directions into a vertical direction. Here and in the following, “vertical” refers, in particular, to a direction perpendicular to the main surface of the carrier.

In particular, the frame comprises a plastic, for example an epoxy, a silicone, a polyester or a polyamide, or consists of one of these materials. Preferably, the frame comprises a plastic that can be formed by compression molding, injection pressing, injection molding or other molding processes.

According to at least one further embodiment of the optoelectronic component, at least the main surface of the carrier comprises a metallic coating. The metallic coating is, for example, a metallic layer or comprises several layers. The metallic coating is preferably arranged directly on the carrier. In particular, a thickness of the metallic coating is smaller than a thickness of the carrier. For example, the thickness of the metallic coating is at most 10% of the thickness of the carrier. Here and in the following, the thickness denotes a spatial extension of the metallic coating in a direction perpendicular to a surface of the carrier to which the metallic coating is applied. For example, the thickness of the metallic coating applied to the main surface of the carrier denotes a spatial extension of the metallic coating in the vertical direction.

In particular, the metallic coating comprises a metal or consists of a metal. For example, the metallic coating comprises gold, silver, nickel, palladium, platinum and/or alloys of at least two of these metals, or consists of one of these materials.

For example, the metallic coating covers at least 50% of the main surface of the carrier. Preferably, the metallic coating completely covers the main surface of the carrier.

Surfaces of the carrier other than the main surface can be at least partially covered by the metallic coating. For example, the back side surface and/or side surfaces of the carrier comprise the metallic coating at least in places. In particular, side surfaces refer to surfaces of the carrier that connect the main surface to the back side surface.

In particular, the metallic coating is configured for increasing the reflectivity of the optoelectronic component for electromagnetic radiation generated and/or detected during operation. By increasing the reflectivity, for example, less electromagnetic radiation is absorbed by the carrier. In particular, this improves the efficiency of the optoelectronic component.

Furthermore, the metallic coating can be configured for making electrical contact with the optoelectronic semiconductor chip. For example, a bond wire is soldered or welded onto the metallic coating, which establishes an electrical connection between the optoelectronic semiconductor chip and the electrical contact surface.

According to at least one further embodiment of the optoelectronic component, an area of the carrier which is in direct contact with the frame is partially free of the metallic coating. For example, the frame encloses side surfaces of the carrier. In particular, the side surfaces enclosed by the frame are at least partially free of the metallic coating and in direct contact with the frame. This preferably improves adhesion and/or a mechanical connection between the frame and the carrier.

According to a preferred embodiment, the optoelectronic component comprises:
a carrier with a main surface,
an optoelectronic semiconductor chip arranged on the main surface of the carrier,
a frame which laterally at least partially encloses the carrier, wherein
at least the main surface of the carrier comprises a metallic coating, and
an area of the carrier which is in direct contact with the frame is partially free of the metallic coating.

In particular, the optoelectronic component described herein is based on the idea to improve the optical properties of the optoelectronic component by means of a partial metallic coating on the carrier, while at the same time making the optoelectronic component highly resistant to corrosion.

In particular, the metallic coating increases the reflectivity of the optoelectronic component for electromagnetic radiation generated during operation. This can improve the efficiency of the optoelectronic component. Furthermore, the frame is in direct contact with the carrier at least in places. In other words, there is no metallic coating between the carrier and the frame at these places. In particular, this means that the frame adheres better to the carrier and the optoelectronic component is therefore less susceptible to corrosion. For example, substances harmful to the optoelectronic semiconductor chip, such as moisture or H₂S, are less likely to penetrate the optoelectronic component along the direct interface between the frame and the carrier than at an interface between the frame and the metallic coating.

In conventional optoelectronic components, the metallic coating is applied to parts of the main surface of the carrier after the frame has been formed, for example. In this case, the area of the main surface of the carrier on which the frame is arranged comprises no metallic coating. For example, the frame is at least partially transparent to electromagnetic radiation at the edge. As a result, the electromagnetic radiation is absorbed more strongly by the uncoated carrier underneath the frame. This leads, for example, to a detrimental loss of brightness of the optoelectronic component. For example, the brightness of the optoelectronic component decreases by approximately 1% to 2%.

Furthermore, it may be impossible or difficult to apply a metallic coating to the main surface of the carrier after the frame has been formed. For example, the optoelectronic component is particularly compact and comprises such small structures that subsequent metallic coating in some areas is not possible or only possible with difficulty.

Alternatively, in conventional optoelectronic components, the carrier can be completely coated with the metallic coating, in particular before the frame is formed. However, this can detrimentally reduce the adhesion between the frame and the carrier. For example, the frame adheres better directly to the carrier than to the metallic coating. In particular, if the frame is only applied directly to the metallic coating, the optoelectronic component comprises, in particular, a reduced resistance to corrosion. For example, harmful substances, such as moisture or H₂S, can penetrate the optoelectronic component more easily at the interface between the frame and the metallic coating.

In the optoelectronic component described herein, the carrier is advantageously only partially covered by the metallic coating. Preferably, the main surface of the carrier is completely covered by the metallic coating, while, for example, side surfaces of the carrier and/or recesses in the carrier that are in direct contact with the frame are free of the metallic coating. This advantageously increases the reflectivity of the optoelectronic component, while the frame adheres better to the uncoated areas of the carrier. The optoelectronic component described herein thus advantageously has a better resistance to corrosion than an optoelectronic component with a completely metal-coated carrier.

According to at least one further embodiment of the optoelectronic component, a portion of the main surface of the carrier, on which the frame is arranged, is at least partially covered by the metallic coating. In particular, the metallic coating is at least partially arranged on the main surface of the carrier between the carrier and the frame. In the case of an at least partially transparent frame, more electromagnetic radiation is thereby reflected by the metallic coating and less electromagnetic radiation is absorbed at the main surface of the carrier. This increases the efficiency of the optoelectronic component.

According to at least one further embodiment of the optoelectronic component, the metallic coating is additionally applied to a surface of the carrier that is opposite to the main surface. In other words, the back side surface of the carrier is covered by the metallic coating.

Preferably, the back side surface is completely covered by the metallic coating. For example, the carrier is completely metal-coated before the metallic coating is at least partially removed from parts of the surface of the carrier that are, in particular, in direct contact with the frame.

According to at least one further embodiment of the optoelectronic component, the carrier comprises a first part and a second part spatially separated therefrom. The first part and the second part are mechanically connected to each other via the frame. In particular, there is no direct electrical connection between the first part and the second part. The first part and the second part are preferably arranged next to each other in a plane of the main surface of the carrier.

The first part and the second part are, for example, configured for electrically contacting the optoelectronic semiconductor chip. For example, the optoelectronic semiconductor chip is a light-emitting diode or a photodiode, wherein a cathode is electrically connected to the first part of the carrier and an anode is electrically connected to the second part of the carrier, or vice versa. The optoelectronic semiconductor chip can be applied to the first part and/or to the second part of the carrier.

Furthermore, the optoelectronic component can comprise a protective diode which is arranged on the first part of the carrier or on the second part of the carrier. In particular, the protective diode is electrically connected to the optoelectronic semiconductor chip in such a way that the optoelectronic semiconductor chip is protected from electrostatic discharges, for example.

According to at least one further embodiment of the optoelectronic component, side surfaces of the first part of the carrier and of the second part of the carrier facing one another are free of the metallic coating. Thus, the frame is in direct contact with the carrier on the side surfaces of the first part and the second part of the carrier that face each other. In other words, no metallic coating is arranged between the carrier and the frame on the mutually facing side surfaces of the first part and the second part of the carrier. This advantageously improves a mechanical connection between the carrier and the frame.

According to at least one further embodiment of the optoelectronic component, the metallic coating has a thickness between 100 nanometers and 10 micrometers, inclusive. For example, the metallic coating has a thickness that is between 0.1% and 10%, inclusive, of the thickness of the carrier. In particular, the thickness of the carrier refers to an average distance between the main surface and the back side surface of the carrier.

An adhesive layer can be arranged between the metallic coating and the carrier. For example, the adhesive layer is applied directly to the carrier and the metallic coating is applied directly to the adhesive layer. The adhesive layer improves an adhesion between the metallic coating and the carrier, for example. Furthermore, the adhesive layer can be configured for preventing or reducing the migration of components of the carrier into the metallic coating, or vice versa. For example, the adhesive layer prevents migration of copper from the carrier into the metallic coating. For example, the adhesive layer has a thickness between 1 nanometer and 100 nanometers, inclusive.

According to at least one further embodiment of the optoelectronic component, the frame projects beyond the semiconductor chip in a direction perpendicular to the main surface of the carrier. For example, the frame projects beyond the semiconductor chip by at least 1 micrometer and/or by at most 400 micrometers. For example, the frame projects beyond the semiconductor chip by 200 micrometers. In particular, the frame projects beyond the optoelectronic semiconductor chip such that an encapsulant can be applied to the optoelectronic semiconductor chip, covering the optoelectronic semiconductor chip on all sides not covered by the carrier. For example, the frame forms a cavity with the carrier and the optoelectronic semiconductor chip is arranged in the cavity.

For example, the encapsulation can be configured for protecting the optoelectronic semiconductor chip from external environmental influences, such as moisture or contact with harmful substances. The encapsulation can also comprise a phosphor for converting the electromagnetic radiation generated by the optoelectronic semiconductor chip during operation.

According to at least one further embodiment of the optoelectronic component, the carrier comprises a recess. The recess is formed, for example, as a blind hole, trench or undercut. The recess can be formed in the main surface, in the back side surface and/or in a side surface of the carrier. In particular, the recess can be formed in the first part and/or in the second part of the carrier.

The carrier can also comprise several recesses, which may be of the same or of a different design. Preferably, the recess is arranged in an area of the carrier on which the frame is formed. In particular, the frame in the recess is in direct contact with the carrier. In other words, preferably no metallic coating is applied within the recess. The recess advantageously improves the mechanical connection between the carrier and the frame.

Furthermore, a method for producing an optoelectronic component is disclosed. In particular, the method is configured for producing an optoelectronic component described herein. All features of the optoelectronic component are also disclosed for the method of producing an optoelectronic component and vice versa.

According to at least one embodiment of the method for producing an optoelectronic component, a carrier with a main surface is first provided.

According to at least one further embodiment of the method, a metallic coating is applied to at least the main surface of the carrier. Preferably, the carrier is completely coated with the metallic coating. In other words, the metallic coating is preferably applied to the entire surface of the carrier. For example, the metallic coating is applied to the carrier by sputtering, vapor deposition, electroplating or by other processes suitable for applying the metallic coating to the carrier.

Furthermore, an adhesive layer can be applied to the carrier before the metallic coating is applied. In particular, the adhesive layer is configured for improving an adhesion between the metallic coating and the carrier.

According to at least one further embodiment of the method, the carrier with the metallic coating applied thereto is etched, such that the carrier is at least partially free of the metallic coating after etching. Etching can, for example, be carried out dry-chemically, wet-chemically or electrochemically. In particular, areas of the carrier with the metallic coating applied thereto are semi-etched or fully etched during etching.

During half etching, at least the metallic coating is removed from an area of the carrier to be etched with the metallic coating applied to it. Preferably, during semi-etching, both the metallic coating is removed in the area to be etched and a recess is formed in the carrier. The recess in the carrier is, for example, a blind hole, a trench or an undercut. During full etching, half etching is preferably carried out on opposite surfaces of the carrier with the metallic coating applied to it, such that an opening is created in the carrier. In particular, the carrier comprises a through hole after full etching or is divided into two separate parts.

The depth of the recess formed in the carrier by etching is not limited. For example, the depth of the recess is one third or one half of the thickness of the carrier. Here, the depth of the recess refers to a maximum spatial extension of the recess in a direction perpendicular to a surface in which the recess is formed.

Instead of etching, recesses or openings in the carrier can also be formed by other abrasive processes, for example by milling or laser ablation. In laser ablation, the material of the metallic coating and/or the carrier is vaporized, in particular in places, by targeted irradiation with a laser beam and thus removed.

According to at least one further embodiment of the method, a frame is formed which laterally at least partially encloses the carrier. The frame is formed, for example, by a compression molding process, an injection molding process or a mold casting process. In particular, the frame is formed in such a way that it is in direct contact with the carrier at least in places. Preferably, the frame is in direct contact with the metallic coating on the main surface of the carrier. Furthermore, an area of the frame is preferably formed within the recess in the carrier. Thus, in particular, a mechanical connection between the frame and the carrier is improved.

According to at least one further embodiment of the method, an optoelectronic semiconductor chip is applied to the main surface of the carrier. For example, the optoelectronic semiconductor chip is mechanically fixed to the metallic coating on the main surface of the carrier using an adhesive and electrically contacted with the carrier via bond wires. The main surface of the carrier can also comprise electrical contact surfaces that are electrically connected to electrical terminal contacts of the semiconductor chip on a side facing the carrier. The electrical contact surfaces can be covered by the metallic coating. For example, the optoelectronic semiconductor chip is soldered onto the electrical contact surfaces or glued on with an electrically conductive adhesive. Thus, in particular, no bond wires are required for the electrical contacting of the optoelectronic semiconductor chip.

According to at least one further embodiment of the method, an area of the carrier which is in direct contact with the frame is partially free of the metallic coating. In particular, the frame is formed such that it is in direct contact with etched areas of the coated carrier. This improves adhesion between the frame and the carrier, in particular.

According to a preferred embodiment, the method of producing an optoelectronic component comprises the following steps:
providing a carrier with a main surface,
applying a metallic coating to at least the main surface of the carrier,
etching the carrier with the metallic coating applied thereto, such that the carrier is at least partially free of the metallic coating after etching,
forming a frame which laterally at least partially encloses the carrier, and
applying an optoelectronic semiconductor chip to the main surface of the carrier, wherein
an area of the carrier which is in direct contact with the frame is partially free of the metallic coating.

Preferably, the steps of the method of producing an optoelectronic component are carried out in the order given above.

According to at least one further embodiment of the method, the metallic coating is applied to the carrier using a galvanic coating process. In particular, the metallic coating is electrochemically deposited on the carrier. For example, a metallic carrier and a silver electrode are immersed in a bath comprising, for example, a silver nitrate solution. By applying an electrical voltage between the silver electrode and the carrier, silver atoms, for example, are released from the electrode, deposited on the surface of the carrier and form a metallic coating of silver.

According to at least one further embodiment of the method, an etching mask is applied to the metallic coating before etching. For example, the etching mask is printed or photolithographically applied to the metallic coating.

According to at least one further embodiment of the method, the etching mask is printed or photolithographically applied to the metallic coating before etching. In particular, the etching mask is configured for protecting areas of the metallic coating and/or the carrier that are not to be etched from an etchant. In particular, the carrier with the metallic coating applied thereto is only etched in areas to which no etching mask is applied.

According to at least one further embodiment of the method, the carrier is separated by etching into a first part and a second part, which are spatially separated from one another. For example, an area of the main surface of the carrier with the metallic coating applied thereto is half etched, so that a first trench is formed in the main surface of the carrier. By further half-etching a corresponding area on the back side surface of the carrier, for example, a second trench is formed, which connects to the first trench and thereby forms an opening in the carrier. The carrier is thus fully etched by the two half etches and separated into the first and second parts.

According to at least one further embodiment of the method, a recess is formed by the etching in an area of the carrier where the carrier is in direct contact with the frame after the frame is formed. For example, the etching forms a blind hole, a trench or an undercut in the main surface of the carrier, in the side surface of the carrier, and/or on the back side surface of the carrier.

According to at least one further embodiment of the method, the frame is formed by a compression molding process, an injection pressing process or an injection molding process. In particular, the compression molding, injection pressing or injection molding is carried out in such a way that the frame adheres to the carrier and to the metallic coating and at least partially encloses the carrier.

According to at least one further embodiment of the method, a plurality of optoelectronic components is produced in composite and the method comprises a step of singulating into a plurality of optoelectronic components. For example, at the beginning of the method, the plurality of optoelectronic components comprises a common carrier on which a frame element is formed by a compression molding process. During singulation, for example, the carrier with the frame element applied thereto is sawn up, such that a plurality of optoelectronic components separated from one another is formed.

### BRIEF DESCRIPTION OF THE DRAWINGS

Further advantageous embodiments and further developments of the optoelectronic component and of the method for producing an optoelectronic component become apparent from the exemplary embodiments described below in conjunction with the figures.

FIG. 1 shows a schematic sectional view of an optoelectronic component according to an exemplary embodiment;

FIG. 2 shows a schematic top view of an optoelectronic component according to an exemplary embodiment;

FIG. 3 shows a schematic bottom view of an optoelectronic component according to an exemplary embodiment; and

FIGS. 4 to 7 show schematic sectional views of various stages of an optoelectronic component after steps of a method for producing an optoelectronic component according to an exemplary embodiment.

Elements that are identical, similar or have the same effect are marked with the same reference signs in the figures. The figures and the proportions of the elements shown in the figures are not to be regarded as true to scale. Rather, individual elements, in particular layer thicknesses, may be shown exaggeratedly large for better visualization and/or understanding.

### DETAILED DESCRIPTION OF ILLUSTRATIVE EMBODIMENTS

The optoelectronic component 1 according to the exemplary embodiment in FIG. 1 comprises a carrier 2 with a main surface 3 on which an optoelectronic semiconductor chip 4 is applied. The carrier 2 comprises, for example, copper or consists of copper. The carrier 2 comprises a first part 21 and a second part 22 spatially separated therefrom, which are arranged next to each other in the lateral direction L in the plane of the main surface 3.

The main surface 3 of the carrier 2 and a back side surface 31 of the carrier 2 opposite the main surface 3 are completely covered by a metallic coating 6. The metallic coating 6 is, in particular, a layer of silver or gold with a thickness of 2 μm, for example. In particular, the metallic coating 6 improves the reflectivity of the optoelectronic component 1 for electromagnetic radiation emitted and/or detected by the optoelectronic semiconductor chip 4.

The carrier 2 is enclosed by a frame 5 in such a way that the frame 5 completely surrounds the optoelectronic semiconductor chip 4 laterally and projects beyond the optoelectronic semiconductor chip 4 in the vertical direction V. Furthermore, the frame 5 mechanically connects the first part 21 of the carrier 2 to the second part 22 of the carrier 2. The frame 5 comprises, for example, an epoxy that is at least partially transparent to the electromagnetic radiation emitted and/or detected by the optoelectronic semiconductor chip 4.

In order to improve an adhesion between the frame 5 and the carrier 2, the carrier 2 comprises recesses 9 in an area on which the frame 5 is formed. Here, the recesses 9 are formed as undercuts on side surfaces 7 of the first part 21 and the second part 22 of the carrier 2 that face away from each other. Alternatively or additionally, the carrier 2 may also comprise recesses 9 on the main surface 3 or the back side surface 31. The recesses 9 can also be formed as blind holes or trenches. The recesses 9 are free of the metallic coating 6. The frame 5 is thus in direct contact with the carrier 2 in the recesses 9. This improves the adhesion between the carrier 2 and the frame 5 and the optoelectronic semiconductor chip 4 is better protected against corrosion.

On the main surface 3 of the carrier 2, the metallic coating 6 is arranged between the frame 5 and the carrier 2. Thus, the metallic coating 6 advantageously also reflects part of the electromagnetic radiation that is transmitted through the frame 5.

The optoelectronic semiconductor chip 4 is a light-emitting diode disposed on the main surface 3 of the first part 21 of the carrier 2. The optoelectronic semiconductor chip 4 is bonded to the metallic coating 6 on the main surface 3 of the carrier 2. Furthermore, the optoelectronic component 1 comprises two bond wires 10 via which the optoelectronic semiconductor chip 4 is electrically connected to the first part 21 of the carrier 2 and the second part 22 of the carrier 2. The optoelectronic component 1 emits the electromagnetic radiation preferably in the vertical direction V.

The first part 21 of the carrier 2 and the second part 22 of the carrier 2 are configured for external electrical contacting of the optoelectronic component 1. For this purpose, the back side surfaces 31 of the first part 21 and the second part 22 of the carrier are formed as electrical contact surfaces. The optoelectronic component 1 is advantageously surface-mountable via the electrical contact surfaces.

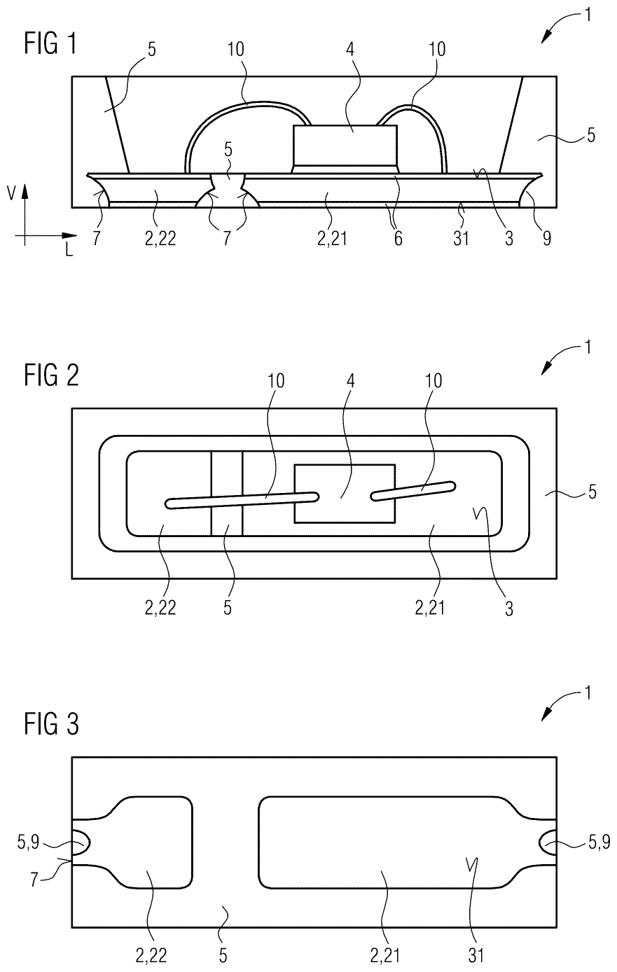

FIG. 2 shows a top view of the main surface 3 of the carrier 2 of the optoelectronic component 1 according to the exemplary embodiment described in connection with FIG. 1. The frame 5 completely surrounds the optoelectronic semiconductor chip 4. Furthermore, the frame 5 is arranged between the first part 21 of the carrier 2 and the second part 22 of the carrier 2 and connects them mechanically.

FIG. 3 shows a top view of a back side surface 31 of the carrier 2 of an optoelectronic component 1 according to the exemplary embodiment described in connection with FIG. 1. Here, the first part 21 of the carrier 2 and the second part 22 of the carrier 2 with the metallic coating 6 applied thereto (not shown here) on the back side surface 31 are at least partially not covered by the frame 5 and form electrical contact surfaces for external electrical contacting of the optoelectronic component 1.

Recesses 9 on the side surfaces 7 of the first part 21 and the second part 22 of the carrier 2 are formed, in particular, as undercuts, which are filled with the material of the frame 5. This improves the adhesion between the frame 5 and the carrier 2.

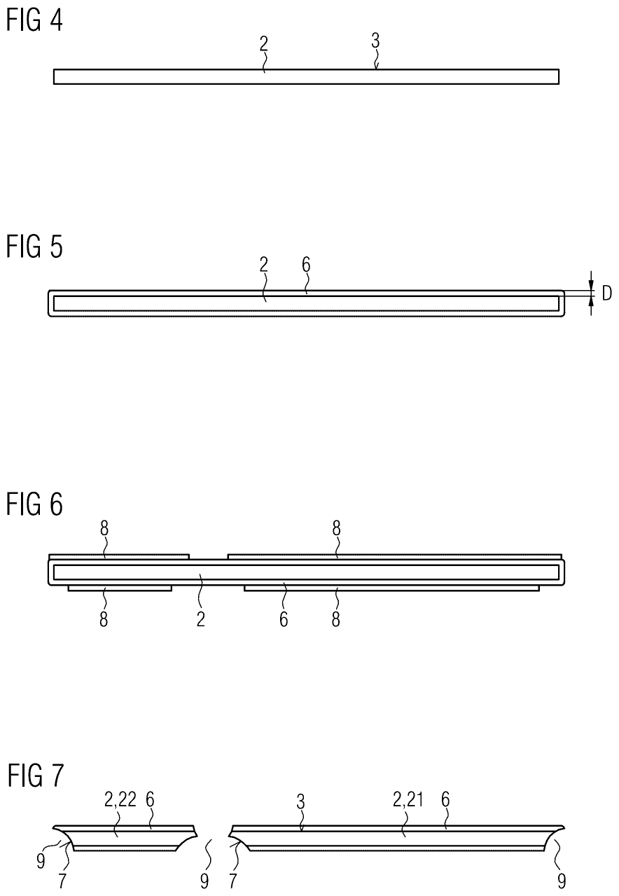

FIG. 4 shows a stage of an optoelectronic component after a step according to an exemplary embodiment of the method, in which a carrier 2 with a main surface 3 has been provided. In particular, the carrier 2 is made of copper.

FIG. 5 shows a stage of an optoelectronic component after a further step according to an exemplary embodiment of the method, in which a metallic coating 6 has been applied to the carrier 2. The metallic coating 6 comprises silver or gold and has been applied to the carrier 2 by a galvanic position process. The metallic coating 6 completely covers the surface of the carrier 2. The metallic coating 6 has a thickness D of between 100 nanometers and 10 micrometers.

FIG. 6 shows a stage of an optoelectronic component after a further step according to an exemplary embodiment of the method, in which an etching mask 8 has been applied to areas of the metallic coating 6. In particular, the etching mask 8 protects underlying areas of the metallic coating 6 and the carrier 2 from an etchant with which the carrier 2 and the metallic coating 6 applied thereto are treated in a subsequent method step. The etching mask 8 is applied, in particular, by a photolithographic process.

FIG. 7 shows a stage of an optoelectronic component after a further step according to an exemplary embodiment of the method, in which the carrier 2 with the metallic coating 6 applied thereto and the etching mask 8 applied thereto has been etched by wet chemical means. In particular, FIG. 7 shows a stage of the optoelectronic component after the etching mask 8 has already been removed.

In particular, recesses 9 are formed in the carrier 2 by etching. A recess 9 breaks through the carrier 2 and divides the carrier 2 into a first part 21 and a spatially separated second part 22. The breakthrough is formed in such a way that side surfaces 7 of the first part 21 and the second part 22 of the carrier 2 facing each other each comprise an undercut. A lateral extension of the undercuts increases with increasing distance from the main surface 3.

Further recesses 9 are formed as undercuts on side surfaces 7 of the first part 21 and the second part 22 of the carrier 2 that face away from each other. In particular, the undercuts improve an adhesion between the carrier 2 and a frame 5, which is formed in a subsequent method step.

The etched side surfaces 7 of the first part 21 and the second part 22 of the carrier 2 are free of the metallic coating 6. The frame 5 formed in the following method step is thus in direct contact with the carrier 2 in the recesses 9. This improves the mechanical connection between the frame 5 and the carrier 2.

After forming the frame 5 in a subsequent method step, the semiconductor chip 4 is applied to the main surface 3 of the carrier 2 in a further method step and electrically contacted with the first part 21 and the second part 22 of the carrier (not shown here).

The invention is not limited to the exemplary embodiments by the description thereof. Rather, the invention includes any new feature as well as any combination of features, which includes, in particular, any combination of features in the patent claims, even if this feature or combination itself is not explicitly stated in the patent claims or the exemplary embodiments.

1.-15. (canceled)

16. An optoelectronic component comprising:
a carrier with a main surface, the carrier comprising a ceramic;
an optoelectronic semiconductor chip arranged on the main surface of the carrier; and
a frame laterally at least partially enclosing the carrier,
wherein at least the main surface of the carrier comprises a metallic coating,
wherein an area of the carrier directly in contact with the frame is partially free of the metallic coating, and
wherein the metallic coating has a thickness between 10 nanometers and 10 micrometers, inclusive.

17. The optoelectronic component according to claim 16, wherein a portion of the main surface, on which the frame is arranged, is at least partially covered by the metallic coating.

18. The optoelectronic component according to claim 16, wherein the metallic coating is additionally located at a surface of the carrier that is opposite to the main surface.

19. The optoelectronic component according to claim 16,
wherein the carrier comprises a first part and a second part spatially separated from the first part, and
wherein the first part and the second part are mechanically connected to each other via the frame.

20. The optoelectronic component according to claim 19, wherein side surfaces of the first part of the carrier and of the second part of the carrier facing one another and are free of the metallic coating.

21. The optoelectronic component according to claim 16, wherein the frame projects beyond the optoelectronic semiconductor chip in a direction perpendicular to the main surface of the carrier.

22. A method for producing an optoelectronic component, the method comprising:
providing a carrier with a main surface;
applying a metallic coating to at least the main surface of the carrier;
etching the carrier with the metallic coating applied thereto such that the carrier is at least partially free of the metallic coating after etching;
forming a frame laterally at least partially enclosing the carrier; and
applying an optoelectronic semiconductor chip to the main surface of the carrier,
wherein an area of the carrier which is in direct contact with the frame is partially free of the metallic coating, and
wherein an etching mask is applied to the metallic coating before etching.

23. The method according to claim 22, wherein applying the metallic coating to the carrier comprises using a galvanic coating process.

24. The method according to claim 22, wherein the etching mask is printed or photolithographically applied to the metallic coating before etching.

25. The method according to claim 22, further comprising separating the carrier by etching into a first part and a second part, which are spatially separated from one another.

26. The method according to claim 22, further comprising forming a recess by etching in an area of the carrier where the carrier is in direct contact with the frame after the frame is formed.

27. The method according to claim 22, wherein the frame is formed by a compression molding process, an injection pressing process or an injection molding process.

28. The method according to claim 22, wherein a plurality of optoelectronic components is produced in composite, and wherein the method further comprises singulating the plurality of optoelectronic components.

29. The method according to claim 22, wherein the optoelectronic component comprises the carrier comprising a ceramic, and wherein the metallic coating has a thickness between 10 nanometers and 10 micrometers, inclusive.
